(19) United States
(12) Patent Application Publication
(10) Pub. No.: US 2024/0234666 A1
(43) Pub. Date: Jul. 11, 2024

(54) LIGHT EMITTING DEVICE AND METHOD OF MANUFACTURING THE SAME

(71) Applicant: ROHM CO., LTD., Kyoto (JP)

(72) Inventor: Kenya HASHIMOTO, Kyoto (JP)

(21) Appl. No.: 18/513,948

(22) Filed: Nov. 20, 2023

(30) Foreign Application Priority Data
Jan. 10, 2023 (JP) 2023-001547

(51) Int. Cl. H01L 33/62

(52) U.S. Cl. CPC H01L 33/62; H01L 2933/0066

(57) ABSTRACT

A light emitting device comprising: a base material including a first main surface and a second main surface, and a first end portion and a second end portion; a light emitting element mounted on the first main surface of the base material and including a first electrode and a second electrode; a first electrode terminal and a second electrode terminal; a covering material; and a sealing material that seals the light emitting element, wherein the first electrode terminal is formed to extend in a first direction, wherein the second electrode terminal is formed to be separated from the first electrode terminal by a distance, wherein the covering material includes: a first covering material that partially covers the first electrode terminal; and a second covering material that partially covers the second electrode terminal, and wherein the first covering material and the second covering material are formed to be separated.

### CROSS-REFERENCE TO RELATED APPLICATION

This application is based upon and claims the benefit of priority from Japanese Patent Application No. 2023-001547, filed on Jan. 10, 2023, the entire contents of which are incorporated herein by reference.

### TECHNICAL FIELD

The present disclosure relates to a light emitting device and a method of manufacturing the same.

### BACKGROUND

In the related art, as one type of light emitting device, for example, a side-view type light emitting device is proposed. In the light emitting device, a light emitting element is mounted on one main surface of a base material. An electrode terminal electrically connected to the light emitting element is formed on the other main surface of the base material.

The side-view type light emitting device is mounted on a mounting substrate so that light emitted from the light emitting element is emitted in parallel to the mounting substrate. Specifically, the light emitting device is mounted on the mounting substrate so that the one main surface on which the light emitting element is mounted is substantially perpendicular to the mounting substrate.

Electrode terminals of the light emitting device and wiring formed on the mounting substrate are electrically coupled by solder fillets. Specifically, the wiring formed on the mounting substrate and the electrode terminals formed on the other main surface of the base material arranged substantially perpendicular to the mounting substrate are electrically connected by the solder fillets.

The electrode terminals in the light emitting device include one electrode terminal electrically coupled to an anode of the light emitting element and another electrode terminal electrically connected to a cathode of the light emitting element. The one electrode terminal and the another electrode terminal are formed on the other main surface of the base material and are formed to be separated by a distance from each other. Further, in the light emitting device, a resist, which is to be a cathode mark, is formed on the other main surface of the base material.

In the manufacturing process of the light emitting device, after a plurality of light emitting elements each electrically connected to the electrode terminal are mounted on one main surface of a substrate, the light emitting device is singulated by dicing the substrate. Thereafter, a plating layer is formed on the surface of the electrode terminal that is not covered with the resist in the singulated light emitting device, and the light emitting device is completed.

### BRIEF DESCRIPTION OF DRAWINGS

The accompanying drawings, which are incorporated in and constitute a part of the specification, illustrate embodiments of the present disclosure.

FIG. 1 is a perspective view of a light emitting device according to an embodiment.

FIG. 2 is a top view of the light emitting device shown in FIG. 1 in the embodiment.

FIG. 3 is a first side view of the light emitting device shown in FIG. 1 in the embodiment.

FIG. 4 is a second side view of the light emitting device shown in FIG. 1 in the embodiment.

FIG. 5 is a bottom view of the light emitting device shown in FIG. 1 in the embodiment.

FIG. 6 is a cross-sectional view taken along cross-sectional line VI-VI shown in FIG. 5 in the embodiment.

FIG. 7 is a plan view showing a step of a method of manufacturing the light emitting device according to the embodiment.

FIG. 8 is a plan view showing a step performed after the step shown in FIG. 7 in the embodiment.

FIG. 9 is a plan view showing a step performed after the step shown in FIG. 8 in the embodiment.

FIG. 10 is a perspective view showing an example of a manner of using the light emitting device in the embodiment.

FIG. 11 is a plan view showing a step of a method of manufacturing a light emitting device according to a comparative example.

FIG. 12 is a plan view for explaining effects of the light emitting device in the embodiment.

FIG. 13 is a detailed plan view for explaining the effects of the light emitting device in the same embodiment.

FIG. 14 is a top view of a light emitting device according to a modification in the embodiment.

FIG. 15 is a first side view of the light emitting device according to the modification in the embodiment.

FIG. 16 is a second side view of the light emitting device according to the modification in the embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Structure of Light Emitting Device

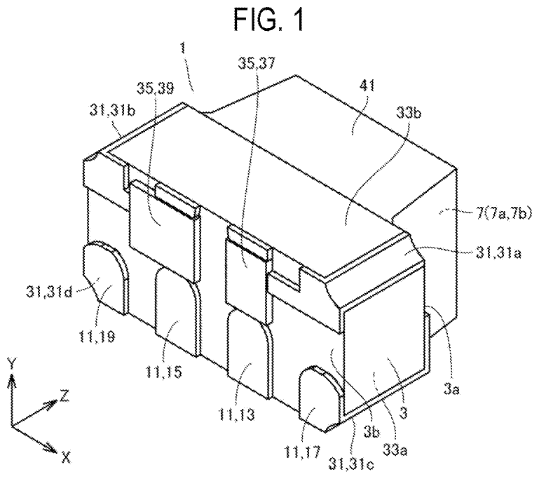

An example of a side-view type light emitting device according to an embodiment will be explained. For the sake of convenience of explanation, the explanation will be made using XYZ coordinate axes as necessary. As shown in FIG. 1, in a light emitting device 1, an LED element 7 is mounted on a side of a first main surface 3a of a base material 3 which has the first main surface 3a and a second main surface 3b facing each other. The base material 3 has a first end portion 33a and a second end portion 33b that extend in an X-axis direction and face each other while separated by a distance from each other in a Y-axis direction.

The LED (Light Emitting Diode) element 7 is sealed with a sealing resin 41 (may be a sealing material). As will be described later, in the side-view type light emitting device 1, in a state where the light emitting device 1 is mounted on a mounting substrate (not shown) parallel to an X-Z plane, a predetermined amount of light is emitted from the LED element 7 toward the positive direction of a Z-axis. Electrode terminals 11 and the like, which are electrically coupled to the LED element 7, are formed on the second main surface 3b of the base material 3.

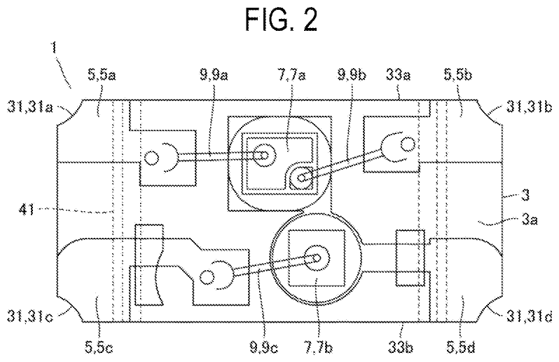

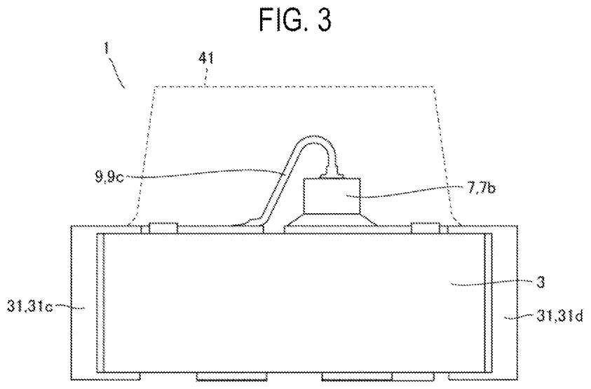

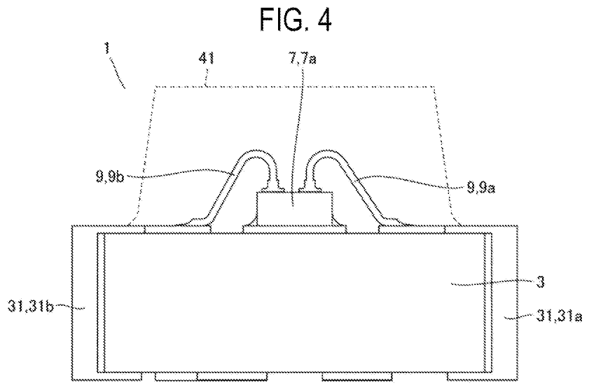

The structure of the light emitting device 1 will be explained in more detail. The base material 3 is formed of, for example, a mixture of BT (Bismaleimide-Triazine) resin and glass cloth. As shown in FIGS. 2, 3, and 4, as the LED element 7, a first LED element 7a and a second LED element 7b are mounted on the first main surface 3a of the base material 3. The first LED element 7a and the second LED element 7b emit different colors of light from each other. The first LED element 7a emits, for example, blue light. The second LED element 7b emits, for example, yellow light. The first LED element 7a and the second LED element 7b are sealed with the sealing resin 41. For example, silicone resin is used as the sealing resin 41.

Lands 5 are formed on the first main surface 3a. The lands 5 include a first land 5a, a second land 5b, a third land 5c, and a fourth land 5d. The LED element 7 and the lands 5 are electrically coupled by wires 9. The wires 9 include a wire 9a, a wire 9b, and a wire 9c. An anode of the first LED element 7a is electrically coupled to the first land 5a by the wire 9a. A cathode of the first LED element 7a is electrically coupled to the second land 5b by the wire 9b. An anode of the second LED element 7b is electrically connected to the third land 5c by the wire 9c. A cathode of the second LED element 7b is electrically connected directly to the fourth land 5d.

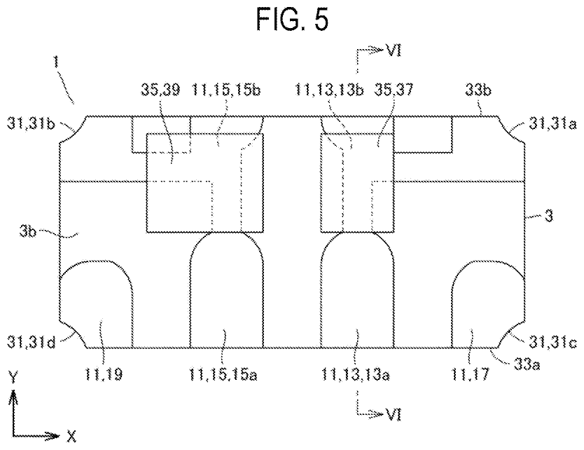

As shown in FIG. 5, the electrode terminals 11 and resists 35 are formed on the second main surface 3b of the base material 3. The electrode terminals 11 include a first electrode terminal 13, a second electrode terminal 15, a third electrode terminal 17, and a fourth electrode terminal 19. The resists 35 are formed as cathode marks. The resists 35 include a first resist 37 (first covering material) and a second resist 39 (second covering material).

The first electrode terminal 13 is formed to extend in the Y-axis direction (first direction) from a side of the first end portion 33a toward a side of the second end portion 33b, in the base material 3. The second electrode terminal 15 is formed to extend in the Y-axis direction (first direction) from a portion of the first end portion 33a side toward the second end portion 33b side in the base material 3. The first electrode terminal 13 and the second electrode terminal 15 are formed to be separated by a distance from each other in the X-axis direction (second direction).

The first resist 37 is formed so as to partially cover the first electrode terminal 13 in such a manner as to expose a portion of the first electrode terminal 13 located at a distance from the first end portion 33a toward the second end portion 33b, of the base material 3. The first electrode terminal 13 includes a first portion 13a of the first electrode terminal 13 that is not covered with the first resist 37, and a second portion 13b of the first electrode terminal 13 that is covered with the first resist 37.

The second resist 39 is formed so as to partially cover the second electrode terminal 15 in such a manner as to expose a portion of the second electrode terminal 15 located at a distance from the first end portion 33a toward the second end portion 33b, of the base material 3. The second electrode terminal 15 has a first portion 15a of the second electrode terminal 15 that is not covered with the second resist 39, and a second portion 15b of the second electrode terminal 15 that is covered with the second resist 39. The first resist 37 and the second resist 39 are formed to be separated by a distance from each other in the X-axis direction (second direction).

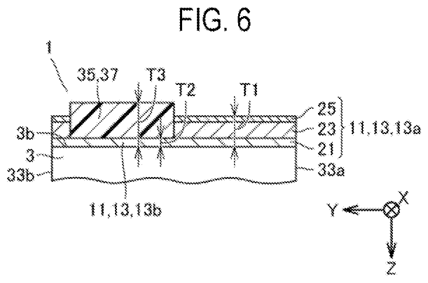

As shown in FIG. 6, the first portion 13a of the first electrode terminal 13 has a copper foil pattern 21, a plating layer 23 (lower layer), and a plating layer 25 (upper layer), which are laminated on the second main surface 3b of the base material 3. The plating layer 23 includes, for example, a copper plating layer, a nickel plating layer, and a gold plating layer. The plating layer 25 includes, for example, a tin plating layer. The second portion 13b of the first electrode terminal 13 has a copper foil pattern 21 formed on the second main surface of the base material 3.

A thickness T1 (first thickness) of the first portion 13a of the first electrode terminal 13 is thicker than a thickness T2 (second thickness) of the second portion 13b of the first electrode terminal 13. A thickness T3 obtained by adding a thickness of the first resist 37 covering the second portion 13b of the first electrode terminal 13 to the thickness T2 is thicker than the thickness Ti. That is, the plating layer 25 is formed so as not to extend beyond an upper surface of the first resist 37. The first portion 15a of the second electrode terminal 15 also has a similar laminated structure as the first portion 13a of the first electrode terminal 13. The second portion 15b of the second electrode terminal 15 also has a similar structure as the second portion 13b of the first electrode terminal 13.

The electrode terminals 11 are electrically coupled to the LED element 7 via through-holes 31 and the lands 5. The through-holes 31 include a first through-hole 31a, a second through-hole 31b, a third through-hole 31c, and a fourth through-hole 31d.

The first electrode terminal 13 is electrically coupled to the anode of the first LED element 7a via the first through-hole 31a and the first land 5a. The second electrode terminal 15 is electrically coupled to the cathode of the first LED element 7a via the second through-hole 31b and the second land 5b. The third electrode terminal 17 is electrically connected to the anode of the second LED element 7b via the third through-hole 31c and the third land 5c. The fourth electrode terminal 19 is electrically connected to the cathode of the second LED element 7b via the fourth through-hole 31d and the fourth land 5d.

The light emitting device 1 according to the embodiment is configured as described above. In the light emitting device 1 described above, due to the first resist 37 covering the first electrode terminal 13 and the second resist 39 covering the second electrode terminal 15 being formed to be separated by a distance from each other in the X-axis direction, when forming the plating layer 25, electrical conductivity between the first electrode terminal 13 and the second electrode terminal 15 may be prevented. This will be described later.

### Method of Manufacturing Light Emitting Device

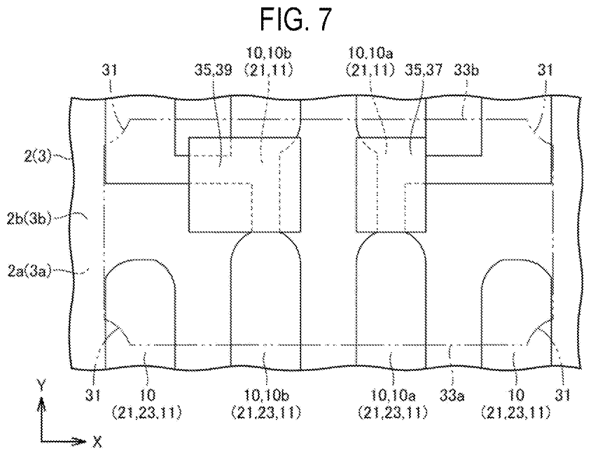

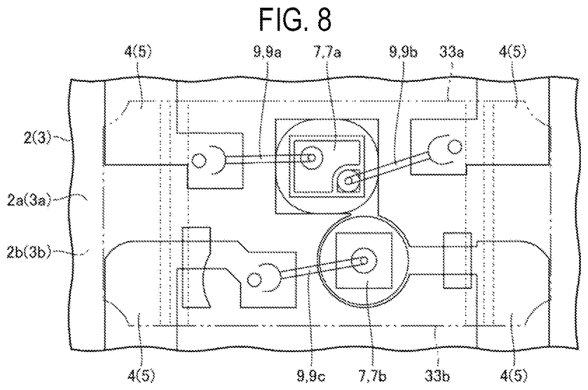

Next, an example of a method of manufacturing the above-described light emitting device 1 will be explained. As shown in FIG. 7, a substrate 2, which is to become the base material 3, is prepared. A plurality of regions (framed by dash-double dotted lines) are defined on the substrate 2 to become the base material 3 of the light emitting device. The substrate 2 has a surface 2a corresponding to the first main surface 3a of the base material 3, and a surface 2b corresponding to the second main surface 3b of the base material 3. Land patterns 4, which is to become the lands 5, is formed on the surface 2a (see FIG. 8).

Conductive patterns 10, which are to become the electrode terminals 11, are formed on the surface 2b of the substrate 2. The conductive patterns 10 are formed by patterning a copper foil formed on the surface 2b of the substrate 2, forming the resists 35 that partially cover the patterned copper foil pattern 21, and then laminating the plating layer 23 on the surface of the exposed copper foil pattern 21 with electrolytic plating treatment. By the electrolytic plating treatment, as the plating layer 23, for example, a copper plating layer, a nickel plating layer, and a gold plating layer are laminated.

The conductive patterns 10 include a first conductive pattern 10a and a second conductive pattern 10b. Each of the first conductive pattern 10a and the second conductive pattern 10b is formed to extend in the Y-axis direction. The first conductive pattern 10a and the second conductive pattern 10b are formed to be separated by a distance from each other in the X-axis direction.

Further, on the surface 2b of the substrate 2, the resists 35 are formed as cathode marks so as to cover the conductive patterns 10. As the resists 35, the first resist 37 and the second resist 39 are formed. The first resist 37 and the second resist 39 are formed to be separated by a distance from each other in the X-axis direction.

The first resist 37 is formed so as to partially cover the first conductive pattern 10a in such a manner as to expose a portion of the first conductive pattern 10a extending from a position of the first end portion 33a of the base material 3 to a position separated by a predetermined distance toward a position of the second end portion 33b of the base material 3. A portion of the first conductive pattern 10a that is not covered by the first resist 37 has a laminated structure of the copper foil pattern 21 and the plating layer 23 (see FIG. 6). The first conductive pattern 10a covered by the first resist 37 has the copper foil pattern 21 (see FIG. 6).

The second resist 39 is formed so as to partially cover the second conductive pattern 10b in such a manner as to expose a portion of the second conductive pattern 10b extending from a position of the first end portion 33a of the base material 3 to a position separated by a predetermined distance toward a position of the second end portion 33b of the base material 3. A portion of the second conductive pattern 10b that is not covered by the second resist 39 has a laminated structure of the copper foil pattern 21 and the plating layer 23. The second conductive pattern 10b covered by the second resist 39 has the copper foil pattern 21.

The land patterns 4 are formed by patterning a copper foil formed on the surface 2a of the substrate 2 and then performing electrolytic plating treatment to the surface of the copper foil. The conductive patterns 10 and the land patterns 4 are electrically coupled via the through-holes 31. After forming openings to expose the land patterns 4 on the surface 2b of the substrate 2, the through-holes 31 in the openings is formed by performing electrolytic plating treatment, so that the conductive patterns 10 and the land patterns 4 are electrically coupled.

Next, as shown in FIG. 8, the LED element 7 is bonded to a predetermined position on the surface 2a of the substrate 2 (die bonding). As the LED element 7, the first LED element 7a and the second LED element 7b are bonded. The first LED element 7a emits, for example, blue light. The second LED element 7b emits, for example, yellow light.

Next, the LED element 7 and the land patterns 4 are electrically coupled by wire bonding (the wires 9). The anode of the first LED element 7a and the land patterns 4 (the first land 5a) are electrically coupled by the wire 9a. The cathode of the first LED element 7a and the land patterns 4 (the second land 5b) are electrically coupled by the wire 9b. The anode of the second LED element 7b and the land patterns 4 (the third land 5c) are electrically coupled by the wire 9c. The cathode of the second LED element 7b is directly coupled to the land patterns 4 (the fourth land 5d).

Next, the LED element 7 bonded to the substrate 2 is sealed. A predetermined mold (not shown) having a cavity is prepared. Next, the substrate 2 on which the LED element 7 is mounted is placed in the mold. Next, by injecting resin into the cavity, the LED element 7 is sealed with the sealing resin 41.

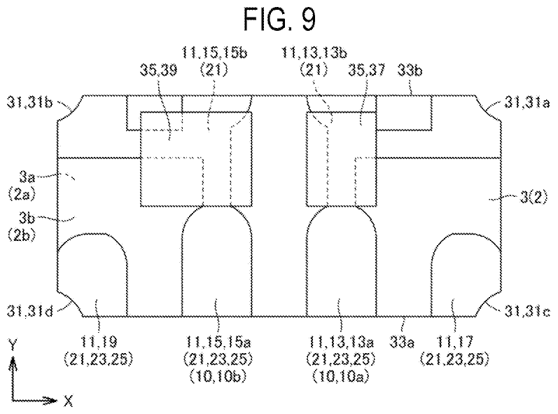

Next, by dicing the substrate 2, portions, which are to become a plurality of light emitting devices formed on the substrate 2, are singulated. Next, the portions, which are to become the singulated light emitting devices, are accommodated in a predetermined container (not shown) and for example, barrel plating treatment is performed. As shown in FIG. 9, by the barrel plating treatment, for example, the tin plating layer 25 is formed on the surface of the plating layer 23 (the conductive patterns 10) that is not covered with the resists 35.

On the surface of the plating layer 23 of the first conductive pattern 10a, the plating layer 25 (first plating layer) is formed. On the surface of the plating layer 23 of the second conductive pattern 10b, the plating layer 25 (second plating layer) is formed. Thus, the electrode terminals 11 are formed on the second main surfaces 3b of the singulated base materials 3 that become the light emitting device 1, and the light emitting device 1 is completed.

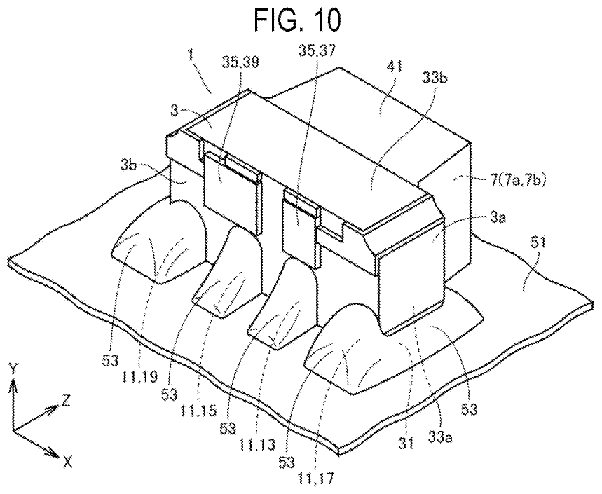

As shown in FIG. 10, the completed light emitting device 1 is mounted on a mounting substrate 51. At this time, the side-view type light emitting device 1 is mounted on the mounting substrate, so that the first main surface 3a (the X-Y plane) of the base material 3 to which the LED element 7 is bonded and the second main surface 3b (the X-Y plane) on which the electrode terminals 11 are formed are substantially perpendicular to the mounting substrate 51 (the X-Z plane). The electrode terminals 11 in the light emitting device 1 are electrically coupled to wiring (not shown) formed on the mounting substrate 51 and having a predetermined width by solder fillets 53.

In the above-described light emitting device 1, due to the first resist 37 covering the first electrode terminal 13 and the second resist 39 covering the second electrode terminal 15 being formed to be separated by a distance from each other in the X-axis direction, when forming the plating layer 25, electrical conductivity between the first electrode terminal 13 and the second electrode terminal 15 may be prevented. This will be explained in comparison with a light emitting device according to a comparative example.

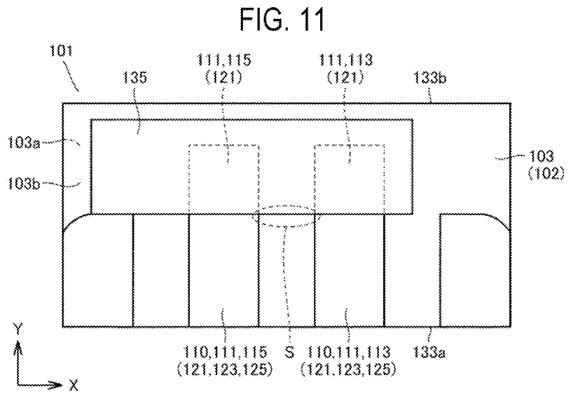

As shown in FIG. 11, in the light emitting device 101 according to the comparative example, an LED element (not shown) is mounted on a first main surface 103a of a base material 103 which is singulated by dicing a substrate 102. Conductive patterns 110 to become electrode terminals 111 are formed on a second main surface 103b of the base material 103. The conductive patterns 110 include a first conductive pattern 113 and a second conductive pattern 115. The first conductive pattern 113 is electrically coupled to an anode of an LED element (not shown). The second conductive pattern 115 is electrically coupled to a cathode of the LED element (not shown).

A resist 135 is formed as a cathode mark so as to partially cover the conductive patterns. The resist 135 is formed to partially cover the conductive patterns 110 in such a manner as to expose a portion of the conductive patterns 110 extending from a first end portion 133a of the base material 103 to a position separated by a predetermined distance toward the second end portion 133b of the base material 103. In the base material 103 immediately after being singulated by dicing, a portion of the conductive patterns 110 covered by the resist 135 has a copper foil pattern 121. A portion of the conductive patterns 110 that are not covered by the resist 135 has a laminated structure of a copper foil pattern 121 and a plating layer 123, and the plating layer 123 is exposed.

Next, barrel plating treatment is performed to the base material 103 singulated by the dicing. By performing the barrel plating treatment, a tin plating layer 125 is formed on the exposed surface of the conductive pattern 110.

At this time, cutting scrap generated during the dicing may adhere to the second main surface 103b of the base material 103, etc. The cutting scrap contains copper of the copper foil pattern 121. Further, by the resist 135 being formed so as to cover the conductive patterns 110, the cutting scrap tends to accumulate along the edge of the resist 135. Moreover, the resist 135 is formed in such a manner that a portion covering the first conductive pattern 113 and a portion covering the second conductive pattern 115 are continuously connected.

Therefore, when the barrel plating treatment is performed, especially within a dotted line frame S between the first conductive pattern 113 and the second conductive pattern 115, it is assumed that a problem may occur in which tin grows with copper contained in the cutting scrap accumulated at the edge of the resist 135 as a nucleus, and the first conductive pattern 113 and the second conductive pattern 115 become electrically conductive.

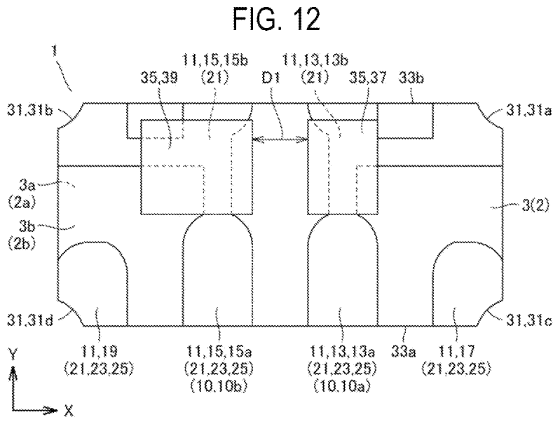

In contrast to the light emitting device 101 according to the comparative example, in the light emitting device 1 according to the embodiment, as shown in FIG. 12, the first resist 37 covering the first electrode terminal 13 and the second resist 39 covering the second electrode terminal 15 are formed to be separated by a distance D1 from each other in the X-axis direction. As a result, even if the cutting scrap accumulates along the respective edges of the first resist 37 and the second resist 39, when forming the plating layer 25, electrical conductivity between the first electrode terminal 13 and the second with the electrode terminal 15 may be reliably prevented.

Further, the fact that the electrode terminals 11 (the conductive patterns 10) are formed toward the portion covered by the resist 35 from the first end portion 33a so as to increase a distance between the first electrode terminal 13 (the first conductive pattern 10a) and the second electrode terminal 15 (the second conductive pattern 10b) also contributes to preventing the electrical conductivity between the first electrode terminal 13 and the second electrode terminal 15. This will be explained in a little more detail.

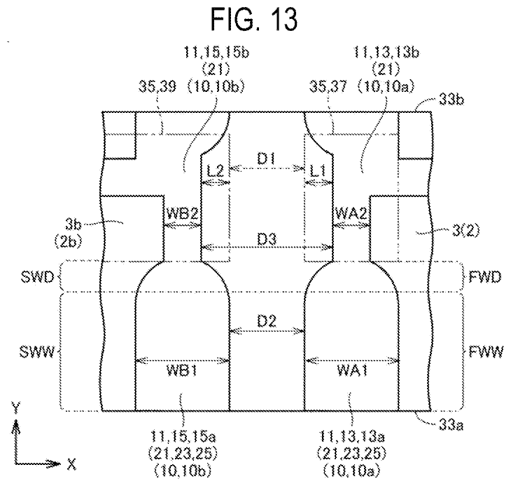

As shown in FIG. 13, the first electrode terminal 13 has the first portion 13a of the first electrode terminal 13 and the second portion 13b of the first electrode terminal 13. The first portion 13a of the first electrode terminal 13 is not covered with the first resist 37 and is exposed on the second main surface 3b. The second portion 13b of the first electrode terminal 13 is covered with the first resist 37.

The second portion 13b of the first electrode terminal 13b has a width WA2. The first portion 13a of the first electrode terminal 13 includes a first wide portion FWW having a width WA1 wider than the width WA2, and a first width decreasing portion FWD whose width is narrowed from the width WA1 to the width WA2. The first wide portion FWW is located on a side of the first end portion 33a. The first width decreasing portion FWD is narrowed in width from the first wide portion FWW toward the second portion 13b of the first electrode terminal 13. When the second main surface 3b is viewed from above, the first width decreasing portion FWD is narrowed in width while being rounded toward the outside.

The second electrode terminal 15 has the first portion 15a of the second electrode terminal 15 and the second portion 15b of the second electrode terminal 15. The first portion 15a of the second electrode terminal 15 is not covered with the second resist 39 and is exposed to the second main surface 3b. The second portion 15b of the second electrode terminal 15 is covered with the second resist 39.

The second portion 15b of the second electrode terminal 15 has a width WB2. The first portion 15a of the second electrode terminal 15 includes a second wide portion SWW having a width WB1 wider than the width WB2, and a second width decreasing portion SWD whose width is narrowed from the width WB1 to the width WB2. The second wide portion SWW is located on a side of the first end portion 33a. The second width decreasing portion SWD is narrowed in width from the second wide portion SWW toward the second portion 15b of the second electrode terminal 15. When the second main surface 3b is viewed from above, the second width decreasing portion SWD is narrowed in width while being rounded toward the outside.

A distance between the first wide portion FWW and the second wide portion SWW is a distance D2. A distance between the second portion 13b of the first electrode terminal 13 and the second portion 15b of the second electrode terminal 15 is a distance D3. The distance D3 is longer than the distance D2. The first width decreasing portion FWD and the second width decreasing portion SWD are formed so as to increase a distance between the first portion 13a of the first electrode terminal 13 and the first portion 15a of the second electrode terminal 15 toward the second portion 13b of the first electrode terminal 13 and the second portion 15b of the second electrode terminal 15 covered with the resist 35 from the side where the first wide portion FWW and the second wide portion SWW are located. As a result, the electrical conductivity between the first electrode terminal 13 and the second electrode terminal 15 may be more effectively prevented.

Further, the distance D3 between the second portion 13b of the first electrode terminal 13 covered by the first resist 37 and the second portion 15b of the second electrode terminal 15 covered by the second resist 39 is set to be longer than the distance D2 between the first wide portion FWW (the first portion 13a of the first electrode terminal 13) and the second wide portion SWW (the first portion 15a of the second electrode terminal 15). As a result, the first resist 37 and the second resist 39 are prevented from being connected.

In order for the first resist 37 to reliably cover the second portion 13b of the first electrode terminal 13, a distance L1 from the end portion of the first resist 37 on the side where the second portion 15b of the second electrode terminal 15 is located to the second portion 13b of the first electrode terminal 13 is determined to be, for example, at least about 50 μm or more. For the second resist 39 as well, as in the case of the first resist 37, a distance L2 is determined to be about 50 μm or more.

Then, when the distance D3 between the second portion 13b of the first electrode terminal 13 and the second portion 15b of the second electrode terminal 15 is equal to the distance D2, the distance D1 between the first resist 37 and the second resist 39 becomes even shorter, and there is a possibility that the first resist 37 and the second resist 39 may become connected. Therefore, by setting the distance D3 to be longer than the distance D2, the first resist 37 and the second resist 39 may be prevented from being connected.

Further, without setting the width WA1 of the first portion 13a of the first electrode terminal 13 (the first wide portion FWW) to be equal to the width WA2 of the second portion 13b of the first electrode terminal 13, the width WA1 of the second portion 13a of the first electrode terminal 13 is set to be wider than the width WA2 of the second portion 13b of the first electrode terminal 13. The width WB1 of the first portion 15a of the second electrode terminal 15 is also set to be wider than the width WB2 of the second portion 15b of the second electrode terminal 15, as in the case of the first portion 13a of the first electrode terminal 13. As a result, the mounting substrate 51 having the existing wiring widths may be used without changing the widths of the wiring (not shown) formed on the mounting substrate 51 (see FIG. 10), which can contribute to reducing production costs.

Further, each of the first width decreasing portion FWD and the second width decreasing portion SWD is narrowed while being rounded toward the outside. This ensures a wider contact area between the solder fillets 53 and the electrode terminals 11 than in a case where each of the first width decreasing portion FWD and the second width decreasing portion SWD is narrowed in width linearly, which can increase the bonding strength.

### Modifications

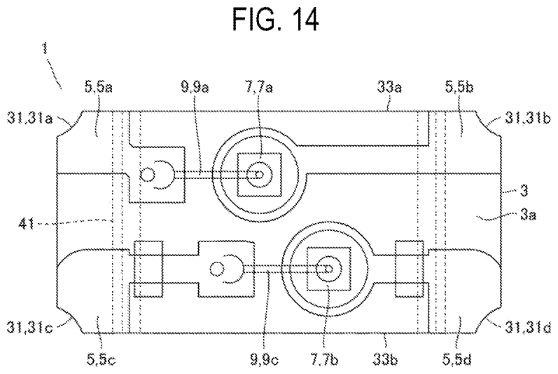

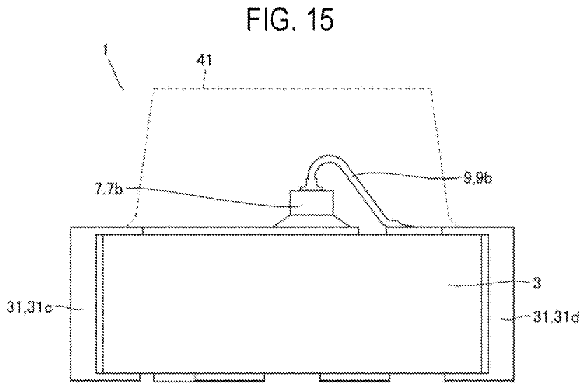

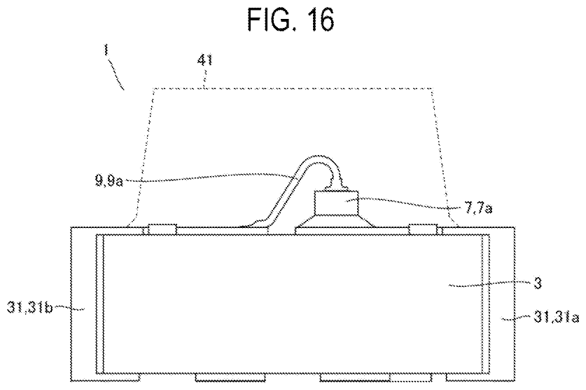

Modifications of the structure for electrically connecting the LED element 7 and the lands 5 will be described. As shown in FIGS. 14, 15, and 16, the first LED element 7a and the second LED element 7b are mounted as the LED element 7 on the first main surface 3a of the base material 3. The anode of the first LED element 7a may be electrically coupled to the first land 5a via the wire 9a, and the cathode of the first LED element 7a may be directly coupled to the second land 5b.

Further, the anode of the second LED element 7b may be electrically coupled to the third land 5c via the wire 9c, and the cathode of the second LED element 7b may be directly coupled to the fourth land 5d. The electrode terminals 11 formed on the second main surface 3b of the base material 3 are similar to the electrode terminals 11 shown in FIG. 5. Also in the light emitting device 1 according to these modifications, when manufacturing the light emitting device 1, the electrical conductivity between the first electrode terminal 11a and the second electrode terminal 11b may be prevented.

Further, in the light emitting device 1 described above, the case has been described in which the plating layer 25 is formed by performing the barrel plating treatment, but other electrolytic plating treatment may be used as a method of forming the plating layer 25. Moreover, the case has been described in which two LED elements 7, the first LED element 7a and the second LED element 7b, are mounted as the LED element 7, but a case in which one LED element 7 is mounted may be used.

The light emitting devices and the methods of manufacturing the same, described in the embodiments, can be combined in various ways as necessary.

The embodiment disclosed this time is an example and is not limited thereto. The present disclosure is indicated by the claims, not the scope described above, and is intended to include all changes within the meaning and scope equivalent to the claims.

The present disclosure includes the following aspects.

### Supplementary Note 1

A light emitting device including:
a base material including:
   a first main surface and a second main surface facing each other; and
   a first end portion and a second end portion facing each other;
a light emitting element mounted on the first main surface of the base material and inclunding a first electrode and a second electrode;
a first electrode terminal electrically coupled to the first electrode and a second electrode terminal electrically coupled to the second electrode, which are formed on the second main surface of the base material;
a covering material that covers the first electrode terminal and the second electrode terminal; and
a sealing material that seals the light emitting element,
wherein the first electrode terminal is formed to extend in a first direction from a side of the first end portion toward a side of the second end portion,
wherein the second electrode terminal is formed to be separated from the first electrode terminal by a distance in a second direction intersecting the first direction and to extend in the first direction from the side of the first end portion toward the side of the second end portion,
wherein the covering material includes:
   a first covering material that partially covers the first electrode terminal so as to expose the first electrode terminal extending from the first end portion of the base material to a position separated by a distance toward the second end portion of the base material; and
   a second covering material that partially covers the second electrode terminal so as to expose the second electrode terminal extending from the first end portion of the base material to a position separated by a distance toward the second end portion of the base material, and
   wherein the first covering material and the second covering material are formed to be separated by a distance from each other in the second direction.

### Supplementary Note 2

The light emitting device of Supplementary Note 1, wherein the first electrode terminal includes:
a first portion of the first electrode terminal formed on the first end portion side and not covered with the first covering material; and
a second portion of the first electrode terminal formed on the side of the second end portion with respect to the first portion of the first electrode terminal so as to be connected to the first portion of the first electrode terminal, and covered with the first covering material, and
wherein the second electrode terminal includes:
a first portion of the second electrode terminal formed on the side of the first end portion and not covered with the second covering material; and
a second portion of the second electrode terminal formed on the side of the second end portion with respect to the first portion of the second electrode terminal so as to be connected to the first portion of the second electrode terminal, and covered with the second covering material.

### Supplementary Note 3

The light emitting device of Supplementary Note 2, wherein the first covering material is formed to cover the second main surface of the base material beyond the second portion of the first electrode terminal over a position separated by a distance on a side where the second portion of the second electrode terminal is located.

### Supplementary Note 4

The light emitting device of Supplementary Note 2 or 3, wherein the second covering material is formed to cover the second main surface of the base material beyond the second portion of the second electrode terminal over a position separated by a distance on a side where the second portion of the first electrode terminal is located.

### Supplementary Note 5

The light emitting device of any one of Supplementary Notes 2 to 4, wherein the second portion of the first electrode terminal has a first width in the second direction, and
wherein the first portion of the first electrode terminal includes:
   a first wide portion located on the side of the first end portion and having a second width wider than the first width; and
   a first width decreasing portion whose width is narrowed from the first wide portion toward the second portion of the first electrode terminal.

### Supplementary Note 6

The light emitting device of Supplementary Note 5, wherein the first width decreasing portion is narrowed in width, while being rounded when the second main surface is viewed in a plane view.

### Supplementary Note 7

The light emitting device of any one of Supplementary Notes 2 to 6, wherein the second portion of the second electrode terminal has a third width in the second direction, and
wherein the first portion of the second electrode terminal includes:
   a second wide portion located on the side of the first end portion and having a fourth width wider than the third width; and
   a second width decreasing portion whose width is narrowed from the second wide portion toward the second portion of the second electrode terminal.

### Supplementary Note 8

The light emitting device of Supplementary Note 7, wherein the second width decreasing portion is narrowed in width, while being rounded when the second main surface is viewed from above.

### Supplementary Note 9

The light emitting device of any one of Supplementary Notes 2 to 8, wherein the first portion of the first electrode terminal has a first thickness,
wherein the second portion of the first electrode terminal has a second thickness, and
wherein the first thickness is thicker than the second thickness.

### Supplementary Note 10

The light emitting device of Supplementary Note 9, wherein a third thickness, which is obtained by adding the thickness of the first covering material covering the second portion of the first electrode terminal to the second thickness of the second portion of the first electrode terminal is thicker than the first thickness.

### Supplementary Note 11

A method of manufacturing a light emitting device, including:
preparing a substrate having a first main surface and a second main surface facing each other, a light emitting element being mounted on the first main surface and a first electrode terminal and a second electrode terminal being formed on the second main surface;
mounting the light emitting element including a first electrode and a second electrode on the first main surface;
sealing the light emitting element;
performing singulation to obtain a base material including a first end portion and a second end portion facing each other, by dicing the substrate; and
performing plating treatment on the second main surface of the diced substrate,
wherein the act of preparing the substrate includes forming:
   a first conductive pattern extending in a first direction;
   a second conductive pattern that is separated by a distance from the first conductive pattern in a second direction intersecting the first direction and extends in the first direction;
   a first covering material that partially covers the first conductive pattern so as to expose the first conductive pattern extending from a position of the first end portion to a position separated by a distance toward a position of the second end portion; and
   a second covering material that partially covers the second conductive pattern so as to expose the second conductive pattern extending from the position of the first end portion to a position separated by a distance toward the position of the second end portion,
wherein in the act of performing the plating treatment,
   a first plating layer is formed on the exposed first conductive pattern to form the first electrode terminal electrically coupled to the first electrode of the light emitting element, and
   a second plating layer is formed on the exposed second conductive pattern to form the second electrode terminal electrically coupled to the second electrode of the light emitting element, and
wherein in the act of preparing the substrate, the first covering material and the second covering material are formed to be separated by a distance from each other in the second direction.

### Supplementary Note 12

The method of Supplementary Note 11, wherein a barrel plating method is applied in the act of performing the plating treatment.

### Supplementary Note 13

The method of Supplementary Note 11 or 12, wherein in the act of preparing the substrate,
the first conductive pattern and the second conductive pattern are separated by a first distance in the second direction at a position of the first end portion, and
the first conductive pattern covered with the first covering material and the second conductive pattern covered with the second covering material are formed to be separated by a second distance longer than the first distance in the second direction.

### Supplementary Note 14

The method of Supplementary Note 13, wherein in the act of preparing the substrate, the first conductive pattern and the second conductive pattern are formed to be separated from the first distance by the second distance in the second direction from the position of the first end portion toward the position of the second end portion.

### Supplementary Note 15

The method of any one of Supplementary Notes 11 to 14, wherein in the act of performing the plating treatment,
the first plating layer is formed so as not to extend beyond an upper surface of the first covering material, and
the second plating layer is formed so as not to extend beyond an upper surface of the second covering material.

### Industrial Applicability

The present disclosure can be effectively used in side-view type light emitting devices.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A light emitting device comprising:
a base material including:
a first main surface and a second main surface facing each other; and
a first end portion and a second end portion facing each other;
a light emitting element mounted on the first main surface of the base material and including a first electrode and a second electrode;
a first electrode terminal electrically coupled to the first electrode and a second electrode terminal electrically coupled to the second electrode, which are formed on the second main surface of the base material;
a covering material that covers the first electrode terminal and the second electrode terminal; and
a sealing material that seals the light emitting element,
wherein the first electrode terminal is formed to extend in a first direction from a sideside of the first end portion toward a side of the second end portion,
wherein the second electrode terminal is formed to be separated from the first electrode terminal by a distance in a second direction intersecting the first direction and to extend in the first direction from the side of the first end portion toward the side of the second end portion,
wherein the covering material includes:
a first covering material that partially covers the first electrode terminal so as to expose the first electrode terminal extending from the first end portion of the base material to a position separated by a distance toward the second end portion of the base material; and
a second covering material that partially covers the second electrode terminal in such a manner as to expose the second electrode terminal extending from the first end portion of the base material to a position separated by a distance toward the second end portion of the base material, and
wherein the first covering material and the second covering material are formed to be separated by a distance from each other in the second direction.

2. The light emitting device of claim 1, wherein the first electrode terminal includes:
a first portion of the first electrode terminal formed on the side of the first end portion and not covered with the first covering material; and
a second portion of the first electrode terminal formed on the side of the second end portion with respect to the first portion of the first electrode terminal so as to be connected to the first portion of the first electrode terminal, and covered with the first covering material, and
wherein the second electrode terminal includes:
a first portion of the second electrode terminal formed on the side of the first end portion and not covered with the second covering material; and
a second portion of the second electrode terminal formed on the side of the second end portion with respect to the first portion of the second electrode terminal so as to be connected to the first portion of the second electrode terminal, and covered with the second covering material.

3. The light emitting device of claim 2, wherein the first covering material is formed to cover the second main surface of the base material beyond the second portion of the first electrode terminal over a position separated by a distance on a side where the second portion of the second electrode terminal is located.

4. The light emitting device of claim 2, wherein the second covering material is formed to cover the second main surface of the base material beyond the second portion of the second electrode terminal over a position separated by a distance on a side where the second portion of the first electrode terminal is located.

5. The light emitting device of claim 2, wherein the second portion of the first electrode terminal has a first width in the second direction, and
wherein the first portion of the first electrode terminal includes:
a first wide portion located on the side of the first end portion and having a second width wider than the first width; and
a first width decreasing portion whose width is narrowed from the first wide portion toward the second portion of the first electrode terminal.

6. The light emitting device of claim 5, wherein the first width decreasing portion is narrowed in width, while being rounded when the second main surface is viewed in a plan view.

7. The light emitting device of claim 2, wherein the second portion of the second electrode terminal has a third width in the second direction, and
wherein the first portion of the second electrode terminal includes:
a second wide portion located on the side of the first end portion and having a fourth width wider than the third width; and
a second width decreasing portion whose width is narrowed from the second wide portion toward the second portion of the second electrode terminal.

8. The light emitting device of claim 7, wherein the second width decreasing portion is narrowed in width, while being rounded when the second main surface is viewed in a plan view.

9. The light emitting device of claim 2, wherein the first portion of the first electrode terminal has a first thickness,
wherein the second portion of the first electrode terminal has a second thickness, and
wherein the first thickness is thicker than the second thickness.

10. The light emitting device of claim 9, wherein a third thickness, which is obtained by adding a thickness of the first covering material covering the second portion of the first electrode terminal to the second thickness of the second portion of the first electrode terminal, is thicker than the first thickness.

11. A method of manufacturing a light emitting device, comprising:
preparing a substrate having a first main surface and a second main surface facing each other, a light emitting element being mounted on the first main surface, and a first electrode terminal and a second electrode terminal being formed on the second main surface;
mounting the light emitting element including a first electrode and a second electrode on the first main surface;
sealing the light emitting element;
performing singulation to obtain a base material including a first end portion and a second end portion facing each other, by dicing the substrate; and
performing plating treatment on the second main surface of the diced substrate,
wherein the act of preparing the substrate includes forming:
a first conductive pattern extending in a first direction;
a second conductive pattern that is separated by a distance from the first conductive pattern in a second direction intersecting the first direction and extends in the first direction;
a first covering material that partially covers the first conductive pattern so as to expose the first conductive pattern extending from a position of the first end portion to a position separated by a distance toward a position of the second end portion; and
a second covering material that partially covers the second conductive pattern so as to expose the second conductive pattern extending from the position of the first end portion to a position separated by a distance toward the position of the second end portion,
wherein in the act of performing the plating treatment,
a first plating layer is formed on the exposed first conductive pattern to form the first electrode terminal electrically coupled to the first electrode of the light emitting element, and
a second plating layer is formed on the exposed second conductive pattern to form the second electrode terminal electrically coupled to the second electrode of the light emitting element, and
wherein in the act of preparing the substrate, the first covering material and the second covering material are formed to be separated by a distance from each other in the second direction.

12. The method of claim 11, wherein a barrel plating method is applied in the act of performing the plating treatment.

13. The method of claim 11, wherein in the act of preparing the substrate,
the first conductive pattern and the second conductive pattern are separated by a first distance in the second direction at a position of the first end portion, and
the first conductive pattern covered with the first covering material and the second conductive pattern covered with the second covering material are formed to be separated by a second distance longer than the first distance in the second direction.

14. The method of claim 13, wherein in the act of preparing the substrate, the first conductive pattern and the second conductive pattern are formed to be separated from the first distance by the second distance in the second direction from the position of the first end portion toward the position of the second end portion.

15. The method of claim 11, wherein in the act of performing the plating treatment,
the first plating layer is formed so as not to extend beyond an upper surface of the first covering material, and
the second plating layer is formed so as not to extend beyond an upper surface of the second covering material.
